(19) United States
(12) Patent Application Publication
(10) Pub. No.: US 2004/0121246 A1
(43) Pub. Date: Jun. 24, 2004

(54) Lithography process to reduce seam lines in an array of microelements produced from a sub-mask and a sub-mask for use thereof

(76) Inventor: David R. Brown, Meridianville, AL (US)

Correspondence Address: KCO Law, P.O. Box 220472, Chantilly, VA, 20153-0472, US

(21) Appl. No.: 10/665,531

(22) Filed: Sep. 22, 2003

Related U.S. Application Data
(60) Provisional application No. 60/411,873, filed on Sep. 20, 2002.

(51) Int. Cl. B28B 7/12; G03C 5/00; B28B 7/32; G03F 9/00; B29D 11/00; G02B 6/18

(52) U.S. Cl. 430/5; 430/322; 264/1.24; 264/2.5; 264/314; 264/335

(57) ABSTRACT

A method and a mask have been optimized to reduce seam lines in replicated structures using lithographic processes. Multiple exposures and sweeps across a substrate using the mask results in the reduction of seam lines in the final developed photosensitive or micro formed structures.

### BACKGROUND OF THE INVENTION

1. Field of the Invention

The present invention relates to a method, apparatus, and system for reducing errors in replicated microstructures arranged in an array. More particularly, it relates to using multiple exposures and/or a mask's meandering shaped edge master pattern to reduce seam lines in replicated arrays of microstructures

2. Background Information

With the advent of Micro-Electro-Mechanical-Systems (MEMS) smaller elements are possible, decreasing the size of devices. Some microsystems particularly those using arrays of microstructures benefit from repeated use of a single mask. In such structures the uniformity of the replication of the microstructures (fabricated array of microstructures) may be important to the microstructure usefulness. There are several errors that show up in a fabricated microstructure formed from an array of microstructures made from one or more masks. One typical error is caused by the seam line.

A seam line is a straight line corresponding to either a raised or lowered microstructure region. The development of a seam line can have at least two causes. First, if a mask is used to project an image pattern in a photoresist on a substrate, very subtle errors in the mask can result in observable seam lines in fabricated arrays of microstructures. Typically, seam lines associated with the writing of a mask are called stitch errors. For example, grayscale masks are typically written with an e-beam or laser writer that scans the beam over a chrome layer forming the mask in either a raster scan or a vector scan. The machines controlling the scanning of the beams are not perfect and produce masks with subtle errors that can result in seam line errors in the microstructures formed by using the masks.

The second source of seam line error results when the stepper (illumination device) is used to step out, illuminate and develop photosensitive layers, to create a larger array of microstructures. For example, micro-displays and detector arrays can be as large as 50 mm across. Making a micro-lens array (MLA) as large as 50 mm requires several smaller arrays of lenses be placed side by side to achieve the final large array. Seam lines are formed because of several effects. For example, the uniformity of the illuminating field (exposure region) across the sub array varies across the field, the placement of the adjacent sub arrays is not perfect, and edge effects may also occur at the edge of the exposure region. Seam lines formed by non perfect placement of adjacent exposure regions, and edge effects occur when the desired fabricated array size (eg. 50 mm) is often larger than a typical mask fabrication exposure region, hence a portion of the array can be patterned in steps across the substrate forming the desired patterns of the desired array of microstructures into a photosensitive layer.

Even methods not using masks (e.g., direct writing methods) are subject to seam line error and stitching errors. In these methods, the pattern is exposed into a photosensitive layer or ablated directly into the substrate using writing tools (e.g. via an electron beam (e-beam), laser or a focused ion beam). These writing tools suffer from the same seam line problems as the step and expose mask method. Writing tools generally comprise the data of a larger area in sub sections that fill out the total area. The machine will write each sub section and then step its stages to write the adjacent sub section. Exposure variations and placement errors cause stitch lines or seam lines to be present in the final array.

To form the patterns for fabricating the microstructures, multiple exposure regions are used, where a single exposure typically corresponds to an above mentioned portion of the array. The multiple exposures are a result of stepping the exposure regions until the substrate upon/from which the array of microstructures are to be microformed is fully patterned. Then the array is created using the pattern by etching the pattern from the substrate.

FIG. 1 illustrates a typical process for patterning a substrate's photosensitive layer when the exposure region is smaller than the desired size of the array of microstructures. In FIG. 1, a substrate 40 has a photoresist layer 25 deposited thereon whose extent corresponds to four sub-array exposure regions 30. The extent of the four sub-array exposure regions corresponds to the desired size of the total array of microstructures The first step exposure 60 exposes the photoresist in the first exposure region to expose the photoresist 25 in the first pattern for one fourth of the final array. In FIG. 3, the sub array exposure region 210 has dimensions X/2, and Y/2 Upon completion of the development of the exposed photosensitive layer in a particular sub array exposure region, the stepper and mask (or the stepper and substrate) are moved one discrete step (either X/2 or Y/2) and another fourth of the total array size is developed. The process is continued until the total photosensitive layer contains the final pattern corresponding to the fully exposed replication array 200. In the example shown in FIG. 3 the sub array exposure region 210 has straight edges 220, and upon stepping there is no overlap of the sub array exposure regions. Thus, current methods of microlens formation results in stitch and seam errors.

### SUMMARY OF THE INVENTION

An exemplary embodiment of the present invention provides method(s) and/or mask(s) for reducing fabrication seam lines in replication processes for arrayed features.

Additional exemplary embodiments of the present invention provide method(s) and/or mask(s) for reducing fabrication seam lines in replication lithographic processes for products having arrayed features.

Further exemplary embodiments of the present invention provide method(s) and/or mask(s) for reducing fabrication seam lines in replication lithographic processes using a grayscale mask.

Additional exemplary embodiments of the present invention provide method(s) and/or mask(s) for reducing fabrication seam lines in replication lithographic processes using multiple overlapping exposures, each exposure contributing to a final exposure of a photosensitive layer.

Further exemplary embodiments of the present invention provide method(s) and/or mask(s) for reducing fabrication seam lines in replication lithographic processes using a mask having a master pattern with meandering shaped edges.

Further exemplary embodiments of the present invention provide method(s) and/or mask(s) for reducing fabrication seam lines in replication lithographic processes using multiple overlapping exposures, each exposure contributing to a final exposure of a photosensitive layer and using a mask having a master pattern with meandering shaped edges.

Further exemplary embodiments of the present invention provide microstructure(s) formed by method(s) and/or mask(s) where the fabrication seam lines have been reduced in the replication lithographic processes forming the microstructure using multiple overlapping exposures, each exposure contributing to a final exposure of a photosensitive layer, where the microstructure can be formed by either etching a substrate using the developed exposed photosensitive layer and/or by curing the developed photosensitive layer into the desired microstructure

These and other exemplary embodiments of the present invention can be realized by providing a method/mask where a photosensitive layer or areacan be placed upon a substrate and partially exposed by each single sweep of an illuminated mask above the photosensitive surface. Thus, after multiple staggered sweeps of irradiation, the photosensitive layercan be fully exposed and the seam lines in the developed patterned photosensitive layer are reduced.

According to an exemplary embodiment of the present invention, the mask used has a master pattern containing multiple sub patterns, to be developed into the photosensitive layer, where the master pattern has meandering shaped edges.

According to an exemplary embodiment of the present invention a microstructure can be formed using the process discussed above, further having the steps of either etching the substrate using the developed exposed photosensitive layer and/or by curing the photosensitive layer forming the microstructure on the substrate.

According to another exemplary embodiment of the present invention a mask need not used, with the photosensitive layer being exposed by direct writing through use of an irradiating beam in this embodiment, the mask step of the process described above can be skipped, being unnecessary due to the direct writing of the irradiation energy onto the photosensitive layer. Data can be arranged such that the writing tool will write the same area on the substrate with multiple partial exposure passes to achieve the desired final exposure Each of these exposure or writing passes can have the data window boundaries (or file boundaries) of the given pass shifted relative to other passes. By doing this, the sub sections that the machine writes will offset from other passes and thus the boundaries between the sub sections will lie in different locations. The data can even be arranged in many smaller files so that the data windows do not line up, producing an uneven edge as described in aforementioned mask/exposure technique

Further scope of applicability of the present invention will become apparent from the detailed description given hereinafter. However, it should be understood that the detailed description and specific examples, while indicating exemplary embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings, which are given by way of illustration only, and thus are not limitative of the present invention, and wherein:

FIG. 1 is an illustration showing the standard method of replicating a master pattern into a photoresist layer, resulting in seam lines in the final developed photoresist, with four unique sub array exposure regions;

FIG. 2 shows an experimental result using the method shown in FIG. 1;

FIG. 3 is a diagram showing four sub array exposure regions such as those shown in FIG. 2, having discrete step lengths of X/2 or Y/2;

FIG. 4 is a diagram showing the characteristics of a mask that can be useable to create sub array exposure regions with meandering edge shapes in accordance with an exemplary embodiment of the present invention;

FIG. 5 is a diagram showing an exposure of a photosensitive layer due to one sweep of the mask across the photosensitive layer in four discrete steps, each step corresponding to a sub array exposure region in accordance with an exemplary embodiment of the present invention;

FIG. 6 shows two of the sweeps shown in FIG. 5, where the start of the each sweep varies and results in a fully exposed replication array resulting in reduced fabrication seam lines in accordance with an exemplary embodiment of the present invention;

FIG. 7 shows four of the sweeps shown in FIG. 5, where the start of each sweep varies and results in a fully exposed replication array resulting in reduced fabrication seam lines in accordance with an exemplary embodiment of the present invention;

FIG. 8 illustrates a microstructure formed by using a method and/or mask in accordance with an exemplary embodiment of the present invention where the microstructure has be formed by etching a substrate using a developed photosensitive layer; and

FIG. 9 illustrates a microstructure formed by using a method and/or mask in accordance with an exemplary embodiment the present invention where the microstructure has been formed by curing a developed photosensitive layer.

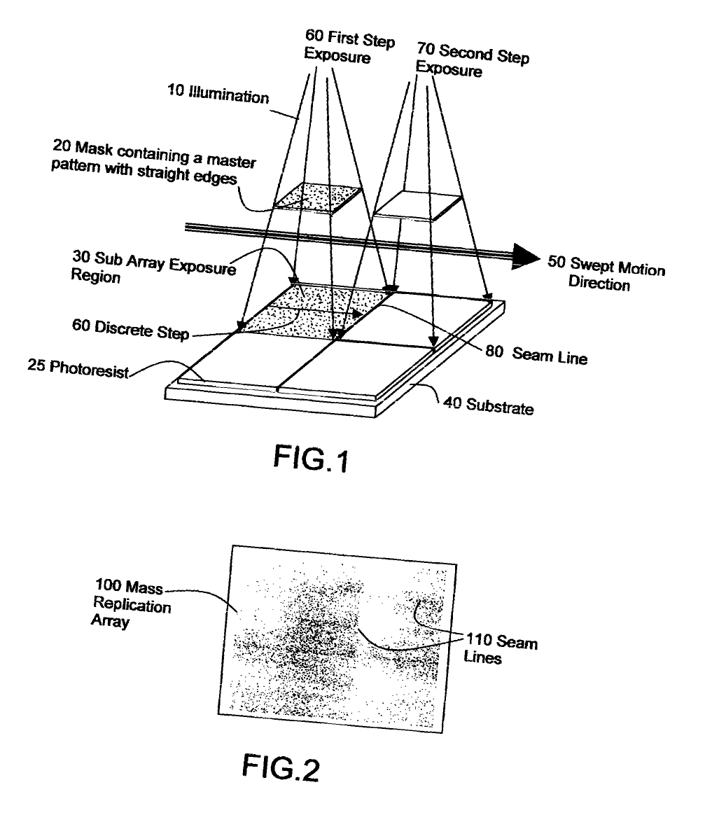

### DETAILED DESCRIPTION

Exemplary embodiments of the present invention provide method(s)/mask(s) that can be used to develop photosensitive layer on a substrate such that microstructures, formed in or on the substrate by using the developed photosensitive layer, have reduced seam lines. In the multiple figures and throughout the disclosure, like figure numbers refer to like elements of the preferred embodiment.

In accordance with various exemplary embodiments of the present invention, a mask can contain a master pattern containing multiple sub patterns. The edge of the master pattern can be intentionally meanderingly shaped to reduce seam lines when said mask can be multiply swept above a substrate. The meandering shape can be any suitable outline that reduces the likelihood that the line between adjacent sub patterns will be at least substantially unnoticeable. The mask can be multiply swept above the substrate, where the multiply swept motion can be used with multiple illumination exposures to develop the photosensitive layer on the substrate with reduced seam lines in the final developed photosensitive layer.

FIG. 4 shows a master pattern image 350, as formed on a photosensitive layer 355, with meandering shaped edges 370. The meandering shaped edges in the master pattern image 370 are the result of illumination 340 of the meandering shaped edges of a master pattern 330 in a mask 300. The meandering shaped edges break up the corresponding fabrication seam line such that the seam line is no longer a straight line but will have a shape similar to the shaped edges. As a result the edge effects are smoothed out along the meandering shaped lines reducing their visibility and undesirable effect on the design The meandering sub-array edge line can be of any suitable contour for accomplishing this purpose, for example by being sinusoidal or curved, or by any suitable pattern that will make the edge less noticeable and which will be effective to reduce the visibility and variation of contour at the edge of the sub array. In an exemplary embodiment the meandering edges use patterns so that opposed edges can be complementary forming, as nearly as possible, a seam without overlap when the mask is stepped and exposure repeated.

The master pattern image 350can be formed by illuminating a master pattern 310 by supplying an illumination beam 340 on a mask 300. The master pattern 310 contains the desired sub pattern 320 that results, upon illumination, of the sub pattern image 360 in the photosensitive layer 355. For example, the sub pattern 320 can be the pattern for one or more individual micro-lenses, and the sub pattern image 360 can be used to develop the photosensitive layer 355 such that the developed photosensitive layer 355 has a pattern of individual microlenses. The sub pattern can be any desired structure and the discussion herein should not be interpreted to limit the sub pattern to a micro-lens sub pattern. Additionally, the master pattern image 350 can be formed by direct write methods, described above. In this case the mask 300 would not be used, instead the master pattern image 350 and sub-pattern image 360 would be formed by exposure of the photosensitive layer 355 or ablated directly into the substrate (not shown) using writing tools and a direct writing process.

The mask 300 can be any type of mask used to expose a photosensitive layer upon illumination of the mask 300. For example, the mask can be a mask in accordance with those described provided in U.S. Pat. Nos. 5,310,623 and 5,310,623 to Gal incorporated herein by reference in their entirety. In addition to the masks described in the Gal patents, other Gray scale mask technologies can be used for the mask 300 and to imprint the desired pattern into the photosensitive layer. For example, in a half tone process, the modulated exposure masking technique, multiple mask technique or any analog technique using High Energy Beam Sensitive (HEBS) glass can all be used to form a mask in accordance with the present invention. In the example shown in FIG. 4 these techniques would be used to partially expose a photosensitive layer 355 to achieve a desired structure.

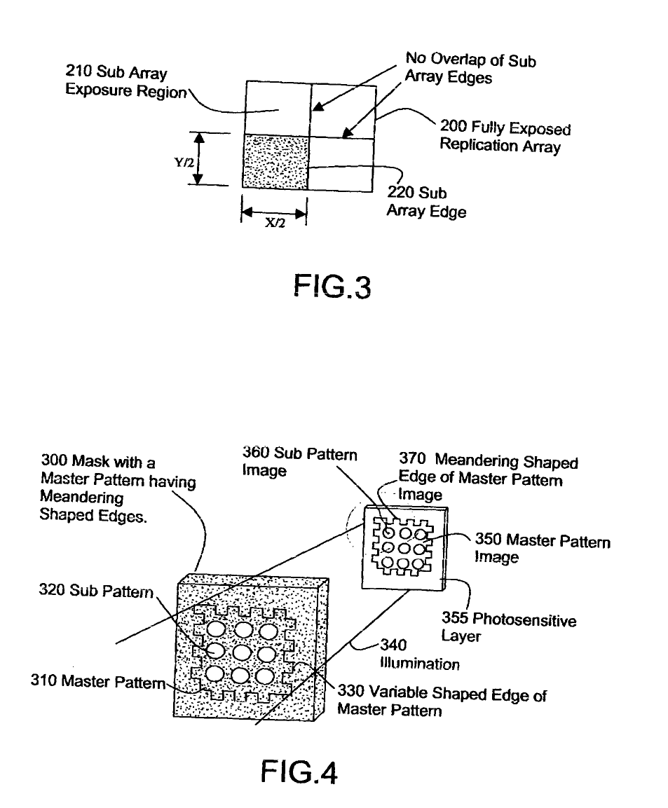

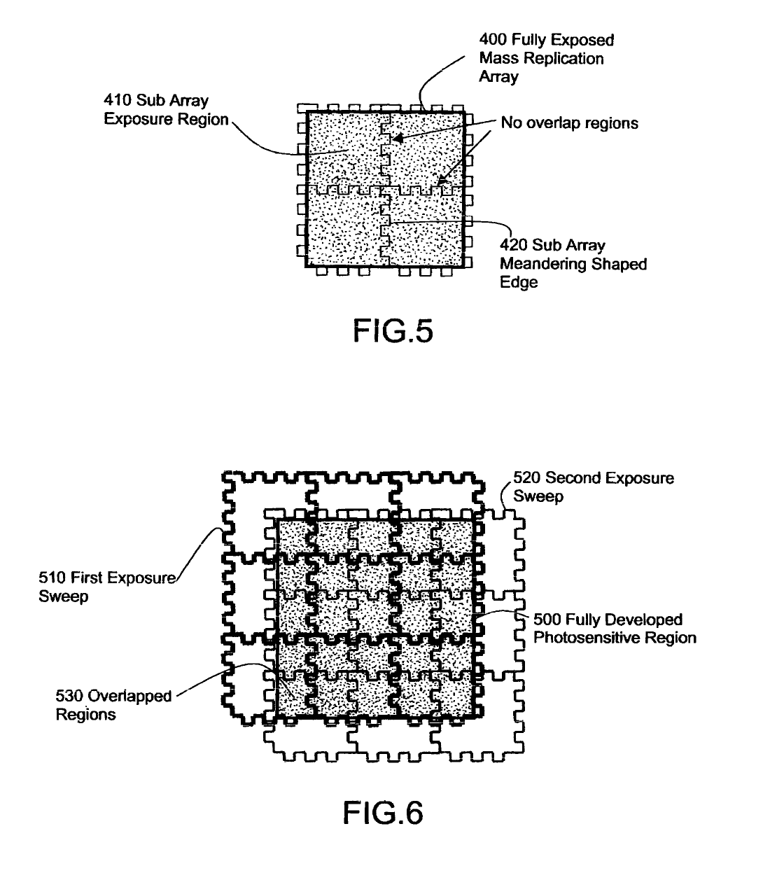

Photosensitive materials used in the photosensitive layer 355 include, but are not limited to, photoresist and PMAMA (polymethyl methacrylate) materials. The resultant master pattern image 350 shown in FIG. 4 corresponds to the sub-array exposure region 210 shown in FIG. 3 and contains an array of sub pattern images 360. In accordance with an embodiment of the present invention, the master pattern image 350 can be used to expose sub-array exposure regions 410 to develop a fully exposed replication array 400, as shown in FIG. 5. Using the mask described with reference to FIG. 4 the sub-array exposure regions will have meandering shaped edges 420. In the exposure example of FIG. 5 the edges of the sub array exposure regions 410 do not overlap. However, another embodiment of the present invention has the regions overlapping. The array of microstructures fabricated from the exposure example shown in FIG. 5 will have more diffuse seam lines, reducing the overall fabrication seam line upon formation of the microstructures using the developed photosensitive layer.

In addition to meandering edged master patterns, fabrication seam lines can be reduced by multiple exposure sweeps. With reference to FIG. 5, an exposure sweep would be the exposure needed to fully expose all of the sub array exposure regions 410 once. In FIG. 5 the fully exposed replication array 400 was fully exposed, by exposing each of the sub array exposure regions 410 having meandering shaped edges 420 once, in a single sweep and subsequently develop the exposed photosensitive surface of the replication array 400. To decrease the effect of seam lines forming between adjacent sub array exposure regions 410, plural offset sweeps of the entire exposure region 500 corresponding to the entire array to be replicated are utilized.

The offset can be selected to the feature repeat pitch of the features described by the sub-array mask 300. However, plural sweeps for exposing the photosensitive layer are applied to fully expose each point in the entire exposure region 500 of replication array 400. This can be accomplished by sweeping the replication array n times, each with approximately 1/n of the total needed exposure and by offsetting the sweeps by 1/n the total size of the sub-array exposure region 410 to be used to generate the array pattern. It should be understood that the distance of 1/n should correspond to an integer multiple of feature pitch of the array. For example, if each sub array mask has a repeat such that the mask repeats completely four times, n may be 2 or 4. In the example of FIG. 3, the microlens repeats three times in each dimension and thus n would be 3. Note that the number of repeats of the pattern in the x and y directions may be different.

In an exemplary embodiment of the present invention a meandering shaped edge master pattern is used and is multiply swept to fully develop the photosensitive layer. Thus each sweep corresponds only to a fraction of the total exposure needed to fully develop the photosensitive layer and thus the seam line associated with a particular sweep will have only a fraction of the intensity (energy) of the one sweep full exposure seam line if the sweeps start at the same place each time then the final seam line is not reduced upon final development of the photosensitive layer. However, if each sweep starts at a different position with respect to the other sweeps, such that the sub pattern image is unaffected, the associated seam line exposure intensities (e.g., energies) for each sweep are reduced, and equal to (E/N) the full intensity exposure (total energy, E) needed divided by the number of sweeps till full exposure (N). Thus, the depth of the seam lines are decreased. Hence, in accordance with an embodiment of the present invention, the full exposure and development of the photosensitive layer with a master image, can occur using a plural number of exposure sweeps.

FIG. 6 shows a two sweep full exposure example in both the x and y directions consisting of a first exposure sweep 510 and a second exposure sweep 520. The energy contained in each exposure is ½ the amount needed to fully develop a photosensitive region. The sweeps overlap in regions 530 forming the fully developed photosensitive region 500. The fully developed photosensitive region 500 is the region that has been exposed to a full exposure after the predetermined number of sweeps, in this example too. In accordance with the embodiments of the present invention multiple sweeps can be used and the discussion herein should not be interpreted to limit the number of sweeps. In the example shown in FIG. 6, the master pattern has meandering shaped edges. However, as mentioned above straight edge master patterns can be used with multiple sweeps to reduce seam lines, and the discussion herein should not be interpreted to limit the type of master patterns or masks used with multiple sweeps.

The same type of method is also applicable to direct writing techniques. In this embodiment the data of the direct write is arranged such that the writing tool will write the same area on the substrate with multiple partial exposure passes to achieve the desired final exposure. This in effect acts as computer controlled “virtual masks.” Each of these exposure or writing passes can have the data window boundaries (or file boundaries) of the given pass shifted relative to other passes in the same manner described above with respect to use of a physical mask. By doing this, the sub-sections that the machine writes will offset from other passes, in a manner described above and illustrated in FIG. 6, and thus the boundaries of said sub sections will lie in different locations. The data can even be arranged in many smaller files so that the data windows don't line up, producing an uneven edge as described in the mask/exposure technique. It should also be understood that a meandering edge of each “virtual mask” can also be desirably used in the direct write technique as described above with reference to the mask replication technique.

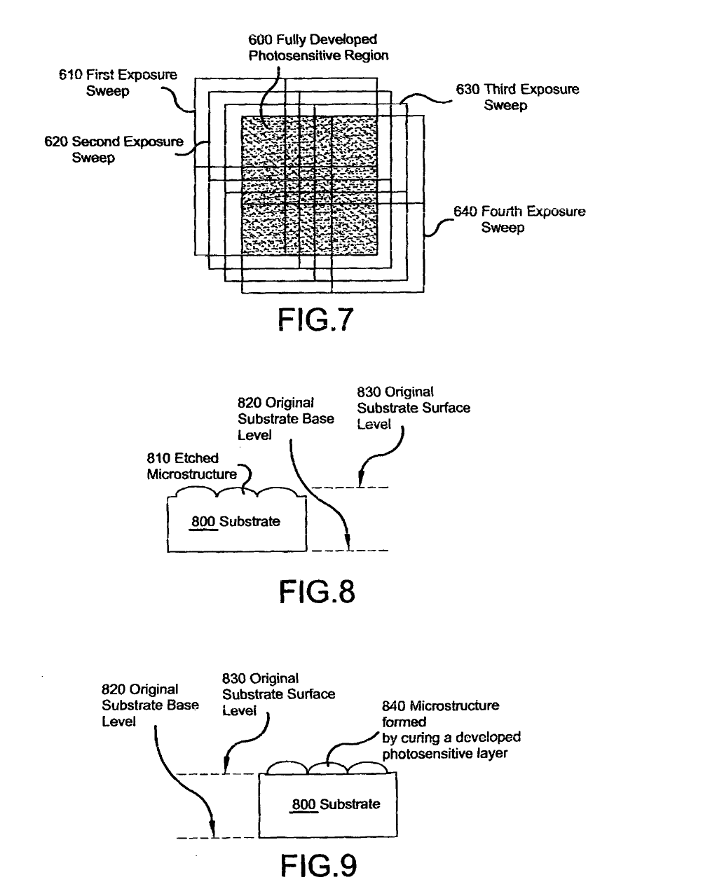

FIG. 7 shows another embodiment of the present invention using four exposure sweeps, 610, 620, 630, and 640, to obtain a fully developed photosensitive region 600 The embodiment shown in FIG. 7 uses master patterns without meandering shaped edges but as shown in FIG. 6 master patterns with meandering shaped edges can be used, and the discussion concerning the embodiment shown in FIG. 7 should not be interpreted to limit the number of sweeps or the master pattern or mask that can be used in the present invention. FIG. 7 illustrated that the repetition of the pattern need not actually be uniform on different sweeps as in FIG. 6. However, if the array pattern to be formed by the mask or direct beam exposure repeats n times in the horizontal direction, the sweep offset can be an offset equal to the repeat period 1/n of the array pattern.

FIG. 8 shows a microstructure formed using a photosensitive layer that has been developed in accordance with embodiments of the present invention. In the embodiment shown in FIG. 8 the substrate 800, having an original substrate surface level 830 and an original substrate base level 820, has been etched to form the microstructure 810. The etched microstructure 810 is formed by etching a fully developed photosensitive layer (now removed and not shown), which rested upon the substrate 800. The microstructure 810 can form an array element of a replication array as discussed above.

In addition to etching the structure using a photosensitive layer that has been developed in accordance with embodiments of the present invention, the microstructures can be formed by curing the developed photosensitive layer resting on the substrate. FIG. 9 shows a microstructure made in accordance with an embodiment of the present invention where the developed photosensitive layer has been cured to form microstructures 840 on the substrate 800.

Many variations in the method and masks used for decreasing the effect of seam lines in accordance with the present invention exist. It will be obvious to one of ordinary skill in the arts to vary the invention thus described. Such variations are not to be regarded as departures from the spirit and scope of the invention, and all such modifications as would be obvious to one skilled in the art are intended to be included within the scope of the following claims.

We claim

1. A method for reducing seam lines in replication lithographic processes, comprising:
a) providing a surface to be patterned and coated with a photosensitive layer;
b) providing an irradiation source for irradiating the photosensitive layer through a mask;
c) providing a mask defining a pattern having a pattern size that is a portion and repeating subset of the overall pattern to be defined on the substrate, said mask defining said repeating subset of the pattern and also having a repeating pattern;
d) performing a first sweep beginning at a initial first sweep position of said mask by:
1) partially exposing the photosensitive layer on said substrate by irradiating said photosensitive layer though exposure from said irradiation source as modulated by said mask to expose a first photosensitive layer portion,
2) stepping said mask across said substrate to position said mask at a second position on said substrate, and
3) repeating said sub-steps 1) and 2) until said photosensitive layer has been partially exposed over the entire surface to be patterned by stepping said mask across said substrate and exposing said photosensitive layer to produce a continuously but partially exposed photosensitive layer; and
e) performing an nth sweep, with said mask physically offset from anyone of said stepped positions of said mask produced by any previous step d)1) or d) 2) by a portion of said pattern size corresponding to a multiple of the repeating pattern to define an nth initial sweep position, said step of performing a nth sweep repeating said sub-steps 1)-3) of step d) from the nth initial sweep position;
said steps d) and e) performing n sweeps of the entire surface to be patterned, each of said n sweeps performing one nth of the total exposure of the entire surface to fully expose said photosensitive layer to enable patterning with reduced seam lines.

2. The method of claim 1 wherein n is 2

3. The method of claim 1 wherein n is 4.

4. The method of claim 1 wherein the initial sweep position for each of said n sweeps is 1/n of the pattern size offset from the previous initial sweep position

5. The method according to claim 1, wherein the edge of the mask is intentionally meandering to further reduce seam lines when said mask is multiply irradiated on each sweep d) and e).

6. The method according to claim 1 where said mask is a grayscale mask.

7. The method according to claim 6 where said mask is formed of High Energy Beam Sensitive (HEBS) glass

8. The mask according to claim 1 where said mask is created by e-beam or laser writing a pattern into a layer.

9. The mask of claim 1 wherein said mask is a binary mask modulating a defocused irradiation to expose the photosensitive layer with illumination varying in intensity as defined by said mask.

10. A method for producing an array of desired microstructures exhibiting reduced seam lines from plural exposures of a mask using replication lithographic processes, comprising:
a) providing a surface to be patterned, coated with a photosensitive layer;
b) providing an irradiation source for irradiating the photosensitive layer through a mask;
c) providing a mask defining a pattern having a pattern size that is a portion and repeating subset of the overall pattern to be defined on the substrate, said mask defining said repeating subset of the pattern and also having a repeating pattern;
d) performing a first sweep beginning at a initial first sweep position of said mask by:
1) partially exposing the photosensitive layer on said substrate by irradiating said photosensitive layer though exposure from said irradiation source as modulated by said mask to expose a first photosensitive layer portion,
2) stepping said mask across said substrate to position said mask at a second position on said substrate, and
3) repeating said sub-steps 1) and 2) until said photosensitive layer has been partially exposed over the entire surface to be patterned by stepping said mask across said substrate and exposing said photosensitive layer to produce a continuously but partially exposed photosensitive layer; and
e) performing an nth sweep, with said mask physically offset from anyone of said stepped positions of said mask produced by any previous step d)1) or d) 2) by a portion of said pattern size corresponding to a multiple of the repeating pattern to define an nth initial sweep position, said step of performing a nth sweep repeating said sub-steps 1)-3) of step d) from the nth initial sweep position;
said steps d) and e) performing n sweeps of the entire surface to be patterned, each of said n sweeps performing one nth of the total exposure of the entire surface to fully expose said photosensitive layer to enable patterning with reduced seam lines; and
f) using the exposed photosensitive mask to form a desired substrate contour.

11. The method according to claim 10, wherein said step f includes,
1) developing the exposed photosensitive layer, and
2) removing a portion of the photosensitive layer, and
3) etching a desired contour defined by the remaining photosensitive layer.

12. The method according to claim 11, wherein said step f) includes,
1) developing the exposed photosensitive layer, and
2) removing a portion of the photosensitive layer, and
3) heat curing the remaining photosensitive layer to form a solid structure.

13. The method of claim 11 or 12 wherein said method further comprises g) electroplating the desired substrate contour to form a master.

14. The method of claim 13 further comprising molding a desired contour from the master.

15. The method of claim 10 wherein the initial sweep position for each of said n sweeps is 1/n of the pattern size offset from the previous initial sweep position.

16. The method according to claim 10, wherein the edge of the mask is intentionally meandering to further reduce seam lines when said mask is multiply irradiated on each sweep d) and e).

17. The method according to claim 10 where said mask is a grayscale mask.

18. The method according to claim 17 where said mask is formed of High Energy Beam Sensitive (HEBS) glass.

19. The mask according to claim 10 where said mask is created by e-beam or laser writing a pattern into a layer.

20. The mask of claim 10 where said mask is a binary mask modulating a defocused irradiation to expose the photosensitive layer with illumination varying in intensity as defined by said mask.

21 An array of desired microstructures, having reduced fabrication seam lines, formed from the process of claims 1 or 10-14.

22. A mask for use in reducing seam lines in replication lithographic processes for manufacture of arrayed features, comprising:
a mask containing a pattern intended control irradiation passing therethrough to expose a photosensitive layer on a substrate, the pattern defining a subset of an array of features to be produced on said substrate by repeated and stepped exposure of said mask to expose the photosensitive layer to a repeating pattern defined by said mask, said mask having opposed first and second intentionally meandering edge portions that reduce seam lines between adjacent exposures of said substrate through stepped positioning of said mask.

23. The mask according to claim 22 where said mask is a grayscale mask.

24. The mask according to claim 22 where said mask is composed of High Energy Beam Sensitive (HEBS) glass.

25. The mask according to claim 22 where said mask is created by e-beam or laser writing a pattern into a layer.

26. The mask of claim 22 wherein said mask is a binary mask modulating a defocused irradiation to expose the photosensitive layer with illumination varying in intensity as defined by said mask.

27. The mask of claim 22 wherein all of the edges of said mask are intentionally meandering edge portions.

28. The mask of claim 27 where the meandering of the intentionally meandering edge portion is generally periodic, with a period substantially smaller than the dimension of the mask.

29. The mask of claim 28 wherein the period of the meandering is at least an order of magnitude smaller than the mask.

30. A method for reducing seam lines in replication lithographic processes, comprising:
a) providing a surface to be patterned, coated with a photosensitive layer;
b) providing an irradiation source for irradiating the photosensitive layer through a mask;
c) providing a mask defining a pattern which is a repeating subset of the pattern to be defined on said substrate;
d) exposing the photosensitive layer on said substrate by irradiating said photosensitive layer though exposure from said irradiation source as modulated by said mask to expose a first photosensitive layer portion;
e) stepping said mask across said substrate to position said mask at a second position on said substrate;
f) repeating said steps d) and e) until said photosensitive layer has been fully exposed by stepping said mask across said substrate and exposing said photosensitive layer to produce a continuously exposed photosensitive layer.

31. The mask according to claim 30 where said mask is a grayscale mask.

32. The mask of claim 30 where the meandering of the intentionally meandering edge portion is generally periodic, with a period substantially smaller than the dimension of the mask.

33. The mask of claim 32 wherein the period of the meandering is at least an order of magnitude smaller than the mask.

34. A method for reducing seam lines in replication lithographic processes, comprising:
a) providing a surface to be patterned, coated with a photosensitive layer;
b) providing an irradiation source for irradiating the photosensitive layer through a mask;
c) providing a control for controlling the irradiation source to irradiate a pattern having a pattern size that is a portion and repeating subset of the overall pattern to be defined on the substrate, said mask defining said repeating subset of the pattern and also having a repeating pattern;
d) performing a first sweep of a portion of the pattern beginning at a initial first sweep position by:
1) partially exposing the photosensitive layer on said substrate by irradiating said photosensitive layer though exposure from said irradiation source as modulated by said control to expose a first photosensitive layer portion,
2) stepping said beam across said substrate to position said beam at a second position on said substrate, and
3) repeating said sub-steps 1) and 2) until said photosensitive layer has been partially exposed over the entire surface to be patterned by stepping said beam across said substrate and exposing said photosensitive layer to produce a continuously but partially exposed photosensitive layer; and
e) performing an nth sweep, with said beam physically offset from anyone of said stepped positions of said beam produced by any previous step d)1) or d)2) by a portion of said pattern size corresponding to a multiple of the repeating pattern to define an nth initial sweep position, said step of performing a nth sweep repeating said sub-steps 1)-3) of step d) from the nth initial sweep position;
said steps d) and e) performing n sweeps of the entire surface to be patterned, each of said n sweeps performing one nth of the total exposure of the entire surface to fully expose said photosensitive layer to enable patterning with reduced seam lines.
